(19) United States
(12) Patent Application Publication
(10) Pub. No.: US 2026/0307908 A1
(43) Pub. Date: Oct. 8, 2026

(54) SUCTION UNIT AND SUCTION DEVICE

(71) Applicant: A O FORMAFLON SWISS AG, Schocherswil (CH)

(72) Inventor: César CARRASCO, Schocherswil (CH)

(73) Assignee: A O FORMAFLON SWISS AG, Schocherswil (CH)

(21) Appl. No.: 19/480,741

(22) PCT Filed: May 3, 2024
(86) PCT No.: PCT/EP2024/062292

§ 371 Date: Oct. 31, 2025

(30) Foreign Application Priority Data
May 3, 2023 (EP) 23171440.3
Feb. 17, 2024 (EP) 24158257.6

(51) Int. Cl. B65G 17/32; B65B 35/18

(52) U.S. Cl. CPC B65G 17/323; B65B 35/18

(57) ABSTRACT

A suction unit, which is suitable for suctioning an object according to the Bernoulli principle, comprises a deflection unit with a deflection head and a peg-shaped mounting element adjoining the deflection head, and a suction body, having a suction plate with a front side facing away from the suction body. Along a channel segment of the inlet channel a plurality of distribution channels are each connected to the inlet channel by a connection channel, which connection channel is closed starting from the front side of the suction plate along a part of the channel segment by the inserted peg-shaped mounting element or a closure member and is open above the peg-shaped mounting element towards the inlet channel. Furthermore, a suction device with several suction units is disclosed.

The invention relates to a suction unit operating according to the Bernoulli principle and a suction device with at least one suction unit operating according to the Bernoulli principle, by means of which objects, in particular individual objects can be picked up from a work process and released again.

In numerous industrial applications, particularly in the food industry, products or objects with predetermined dimensions must be provided for packaging. Foodstuffs such as bread, sausage products, or cheese are often divided into thin slices or pieces and packaged. In other technical areas, plate-shaped workpieces such as wafers, circuit boards, foils, paper, wood veneer, and the like are manufactured and made available for further processing. In addition to disc-shaped objects, objects of other shapes, such as round or elongated shapes, often need to be captured.

The objects must be picked up gently at a pick-up point and delivered unchanged, i.e. without deformation, damage, or contamination, at a delivery point. Instead of mechanical gripping tools, suction devices are therefore often used, preferably operating on the Bernoulli principle.

According to DE202006016833U1, Bernoulli suction units usually consist of an axially symmetrical base body through which a gaseous medium (compressed air, inert gas, etc.) flows from at least one nozzle in the direction of an object to be lifted. When hitting the object, the gaseous medium between the object unit and the base body of the suction unit is deflected in a radial direction at high flow velocity. According to the Bernoulli equation, the kinetic energy and the specific pressure energy are always constant. Hence, the area of high flow velocity, a correspondingly reduced pressure results, by means of which the object is suctioned.

In order to reduce the pressure force counteracting the suction force that arises when the media flow hits the object, known suction units deflect the media flow in a radial direction before it hits the object. A plate-shaped deflection unit is held in front of the inflowing gas so that it is deflected radially through a ring gap and guided away to the side. DE202006016833U1 shows suction units in which the plate-shaped deflection unit is integrally connected to the base body. The manufacture of such a suction unit with the integrally integrated deflection unit involves a high level of manufacturing effort.

US2022289500A1 describes suction units comprising a deflection unit with a deflection head and a peg-shaped mounting element connected to the deflection head, and a suction body. The suction body comprises a suction plate with a front side facing away from the suction body, an inlet channel that is closed at the front after the deflection head has been inserted, and several distribution channels branching off from the inlet channel, through which a gaseous medium can be introduced from the inlet channel to the front side of the suction plate into a deflection channel or annular gap, which is delimited on one side by the front side of the suction plate and on the other side by the deflection head of the deflection unit, and through which deflection channel or annular gap the gaseous medium can be led away from the deflection unit. The manufacture of this suction unit also involves high production costs. The distribution channels are incorporated into the suction body by means of drill holes, which requires intensive mechanical processing.

Suction devices with multiple suction units allow to grasp and transport several objects simultaneously, either manually or mechanically. Suction devices of this type usually have a complex structure and do not allow the suction units to be mounted in a simple manner.

The present invention is therefore based on the object of creating an improved suction unit that operates according to the Bernoulli principle. Furthermore, an improved suction device with at least one suction unit operating according to the Bernoulli principle is to be created.

Inventive suction units are designed to enable objects of any size and shape to be securely grasped and released in a controlled manner.

The suction units shall have a base body that can be manufactured with minimal production effort. The suction units shall be able to be produced cost-effectively in simple processes with short cycle times. Complex mechanical processing shall be avoided.

Inventive suction devices shall be cost-effective to manufacture and shall be adaptable to the requirements of users in different technological fields with minimal manufacturing effort.

Suction units shall be easy to assemble and disassemble so that the suction device can be quickly adapted to a given work process. The suction units shall be mountable without tools using simple fasteners.

The suction device shall be suitable for use as a hand tool or for machine use, for example by automatic machines or robots.

This task is solved by a suction unit and a suction device, which have the features specified in claims 1 and 11 respectively. Advantageous embodiments of the invention are specified in further claims.

The suction unit, which is suitable for suctioning an object according to the Bernoulli principle, comprises a deflection unit with a deflection head and a peg-shaped mounting element adjoining the deflection head, and a suction body,
which suction body has a suction plate with a front side facing away from the suction body,
which suction body has an inlet channel which extends through the suction body to the front side of the suction plate and into which inlet channel the peg-shaped mounting element is inserted from the front side of the suction plate, and
which suction body has a plurality of distribution channels branching off from the inlet channel,
   wherein through the distribution channels a gaseous medium is introducible from the inlet channel to the front side of the suction plate into a deflection channel, which is delimited on one side by the front side of the suction plate and on the other side by the deflection head of the deflection unit.

According to the invention, along a channel segment of the inlet channel the distribution channels are each connected to the inlet channel by a connection channel, which connection channel is closed starting from the front side of the suction plate along a part of the channel segment by the inserted peg-shaped mounting element or a closure member and is open above the peg-shaped mounting element towards the inlet channel.

Hence, the suction body does not have any distribution channels that are completely enclosed between the channel inlet and the channel outlet and that must be inserted into the suction body by mechanical working processes, for example by drilling. The suction body can be manufactured in a single operation by primary forming or by a primary forming process, in particular an injection moulding process.

Primary forming is a main group of manufacturing processes and, according to DIN 8580, combines all manufacturing processes in which a solid body with a geometrically defined shape is produced from a formless material. Primary forming is used to produce the initial shape of a solid body and to create material cohesion (see https://de.wikipedia.org/wiki/Urformen). Die casting, injection moulding or compression moulding processes can be used advantageously.

Plastics can therefore be advantageously transferred from a liquid or plastic state into the final shape of the suction body, eliminating the need for subsequent mechanical processing. The inventive suction units can therefore be manufactured cost-effectively without mechanical processing.

The connection channels and thus the distribution channels are preferably closed first by the peg-shaped mounting element of the deflection unit in an area between the inlet channel and the front side of the suction plate. The gaseous medium can therefore only be guided from the inlet channel to outlet openings of the distribution channels, which are provided at defined points on the front side of the suction plate.

Preferably, the connection channels are closed by the deflection unit. However, it is also possible to use a closure member with the same effect, which, for example, has a sealing sleeve that can be inserted into the inlet channel and a ring flange connected to it. The mounting element of the deflection unit is then inserted or screwed into the closure member.

Transparent plastics are preferably used for manufacturing the suction body and the deflection unit, which allow an object held by the suction unit to be visually monitored and/or inspected.

The distribution channels are arranged at regular or irregular intervals and preferably extend along the surface of a cone or along a curve, possibly asymptotically to the suction plate, concentrically to the longitudinal axis, towards the outside. The direction of discharge of the medium can be influenced as desired by appropriate shaping and inclination of the distribution channels.

The connection channels are preferably implemented as longitudinal slots that can easily be closed. The connection channels have a first channel opening adjoining the channel segment of the inlet channel and a second channel opening adjoining the front side of the suction plate.

Preferably, the deflection unit is provided with a sealing ring connected to the mounting element, which rests against the second channel opening and closes the connection channels at the front. The sleeve-shaped closure member provided with a ring flange has the same function.

In addition or alternatively, it is preferable that the mounting element or the sleeve-shaped closure member is provided with sealing bodies corresponding to the number of distribution channels, which can be inserted into the connection channels in order to preferably fill and seal them completely. The sealing bodies are preferably designed to be complementary to the connection channels.

The suction body is preferably connected in one piece or detachably to a suction basket, the inside of which is connected to the suction plate or spaced apart from the suction plate, and which encloses a receiving channel having a channel opening dimensioned such that individual objects can be inserted into the receiving channel or into at least one shaping on the underside of the suction basket.

Preferably, the suction basket has at least one basket opening, preferably a slit-shaped basket opening, which is preferably located approximately at the height of the deflection head of the deflection unit or at a distance from the suction plate which is, for example, in the range of 1 mm to 20 mm. Advantageously, several basket openings may also be provided, which are preferably arranged in one plane or in several planes axially to the longitudinal axis of the suction unit, offset from one another.

Preferably, the channel opening of the suction basket is enclosed by a ring plate aligned vertically or inclined to the suction basket.

The suction plate and/or the ring plate are preferably provided with outwardly extending channels which ensure the passage of the medium when an object is coupled to the suction unit.

The suction body can advantageously be provided with retaining elements, such as mouldings, bores, rings or a ring groove, by means of which the suction body can be mounted on a device connection, in particular a suction device. The suction unit can, for example, be placed with the suction body on an outlet opening of the suction device and fixed by means of a fastening element, such as a mounting clip, a mounting bracket or the like. Preferably, at least one sealing ring is provided between the device part having the outlet openings and the suction body, which ensures that the medium escaping from the outlet openings is only passed through the connected suction unit.

Inventive suction units, for example in the embodiments described, which are provided with at least one holding element, or conventional suction units, which are provided with at least one holding element with the same function, can be advantageously integrated into inventive suction devices. Inventive suction devices comprise a distribution device, which has a hollow body with at least one inlet opening and several outlet openings, and fastening elements, which are permanently or detachably connected or connectable to the distribution device and which each form a device connection at an outlet opening and can hold an associated suction unit on the holding element above an associated outlet opening.

The hollow body can be a simple polygonal or round tube that can be provided at minimal cost and can be equipped with at least one inlet opening and outlet openings on one or more sides.

The fastening elements are preferably designed as mounting clips or mounting brackets and are preferably made of elastic material, metal or plastic. Fastening elements can, for example, be attached to mounting elements, in particular flange elements, which are provided on the distribution device. However, fastening elements are preferably provided which can be mounted without such mounting elements.

Such a fastening element is preferably designed as a mounting clip and, in a preferred embodiment, comprises a base plate to which two side walls are connected, and a cover plate, preferably inclined downwards, which is connected to one of the side walls on the side opposite the base plate. The base plate has a mounting slot, which is adjoined by an access opening on at least one of the sidewalls, which access opening is wider than the mounting slot and into which a holding element of a suction unit, which is preferably designed as a mounting disc, is insertable or inserted. The mounting clip is mounted in such a way that the mounting slot is located above an outlet opening and the holding element of the suction unit can be pushed over the associated outlet opening. The cover plate acts as a spring element that pulls the mounting disc against the distribution device. After mounting, the mounted mounting clip clamps around the distribution device and holds the mounted suction unit securely in position.

The mounting clip can be advantageously manufactured by bending an elastic metal plate or made of plastic and can easily be mounted on a distribution device. The parts of the mounting clip are preferably adapted in whole or in part to the shape of the distribution device. The base plates and side plates are therefore flat, rounded and/or edged, as appropriate.

It is not necessary to install a suction unit at each of the outlet openings. Unused outlet openings are closed with a sealing element, such as a screw.

The distribution device can be adapted to different processes and machines, in particular production machines or production lines. Distribution devices can, for example, be tubular, cuboid, single-armed or multi-armed or cross-shaped or have any other shape. The distribution devices can also be made of any material, such as metal or plastic. The distribution devices can be constructed as a single piece or in a modular fashion so that they can be assembled by the user as required.

In preferred embodiments, the distribution devices are circular, plate-shaped or wheel-shaped, or have a rectangular or polygonal profile. For example, the distribution device comprises two round side plates that are connected peripherally by a cylindrical circular frame and delimit a cavity. The outlet openings and the fastening elements associated with the outlet openings can be provided optionally on the side plates and/or on the circular frame. The distribution device, which is preferably designed to be rotationally symmetrical, allows objects to be picked up at a first location and released again at a second location by means of the suction devices.

In another preferred embodiment, the distribution device has a polygonal cross-section with multiple sides, one or more of which are provided with outlet openings and fastening elements by means of which the mounted suction units are held.

The suction device can be designed in such a way that it can be operated manually or mechanically, for example by a machine or robot.

The outlet openings can preferably be closed either completely or partially by means of mechanical or controllable electromechanical closing means, so that mounted suction devices can be activated individually.

The invention is explained in more detail below with reference to drawings. These show:

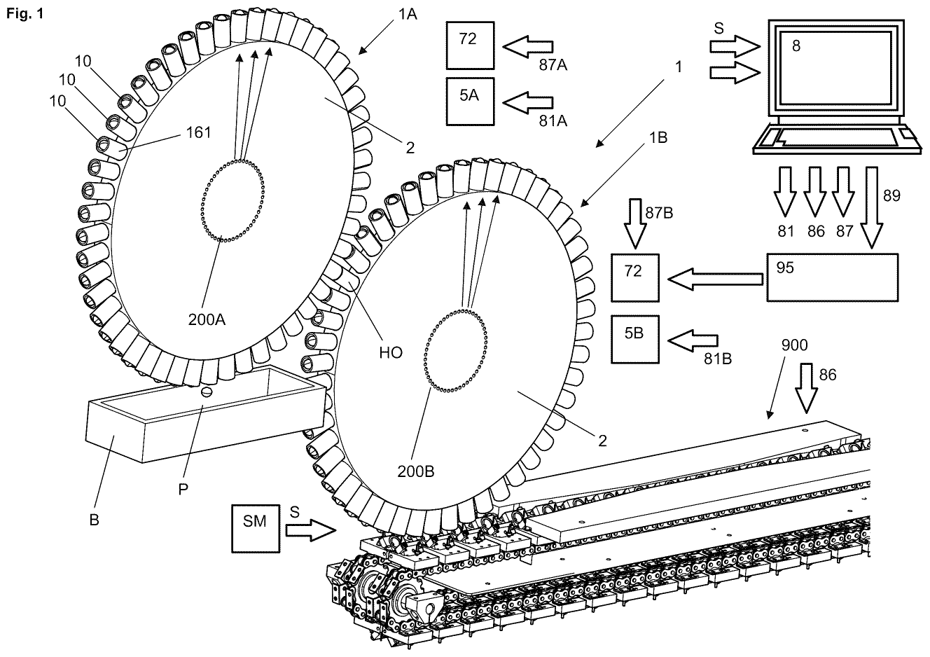

FIG. 1 a combined suction device 1 with two wheel-shaped suction devices 1A, 1B, which are equipped peripherally with suction units 10, from which objects P are picked up at a pick-up location and delivered to a conveyor device 6 at a delivery location;

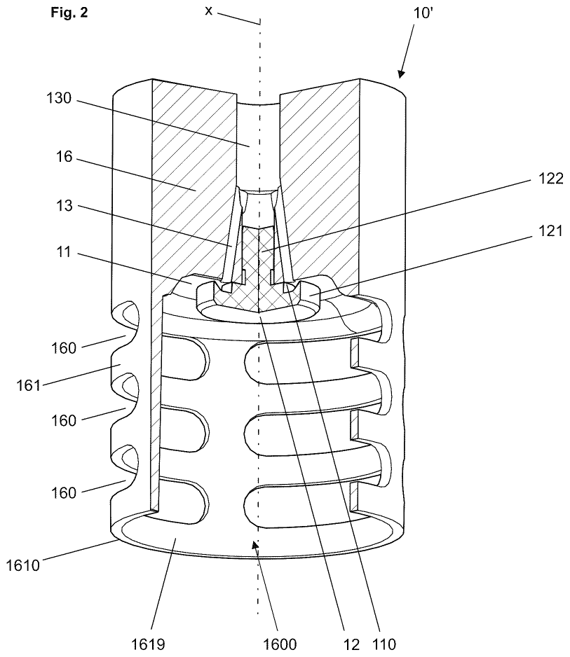

FIG. 2 in sectional view, a known suction unit 10′ with a deflection unit 12, which comprises a deflection head 121 and a peg-shaped mounting element 122 adjoining the deflection head 121, and with a suction body 16, which comprises a suction plate 11 adjoining the suction body 16 having a front side facing away from the suction body 16, a suction basket 161 adjoining the suction plate 11, an inlet channel 130 and several distribution channels 13 branching off from the inlet channel 130, which were drilled into the suction body 16 starting from the front side of the suction plate 11 up to the inlet channel 130;

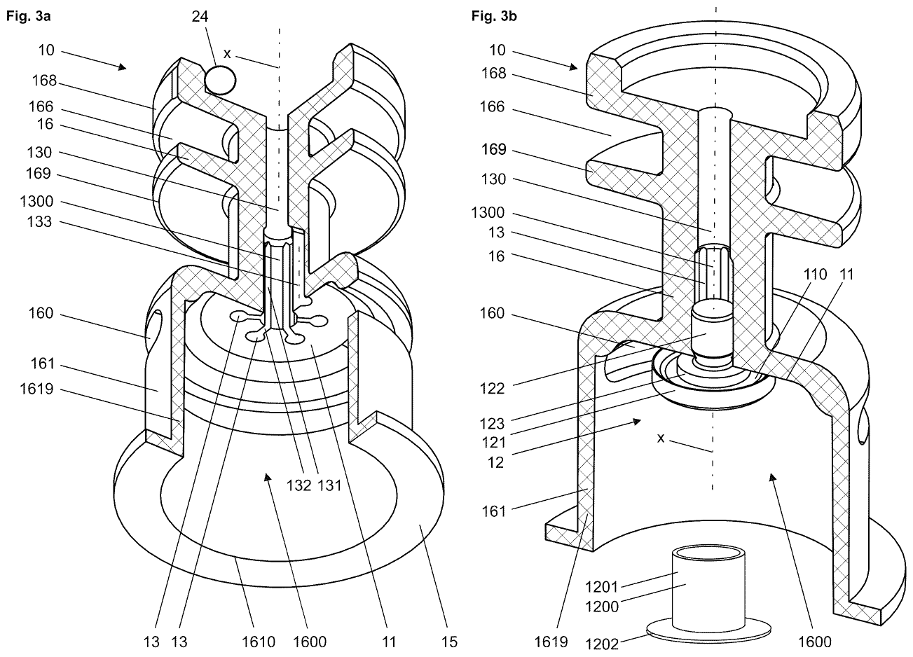

FIG. 3a an inventive suction unit 10, without a deflection unit 12, comprising a suction body 16, a suction plate 11 adjoining the suction body 16 with a front side facing away from the suction body 16, a suction basket 161 adjoining the suction plate 11, an inlet channel 130 and several distribution channels 13 branching off from the inlet channel 130, which are each connected to the inlet channel 130 each by a connection channel 133 along a channel segment 1300 of the inlet channel 130;

FIG. 3b the suction unit 10 of FIG. 3a with the deflection unit 12 inserted into the inlet channel 130, for example as shown in FIG. 2, by which the distribution channels 13 are closed towards the inlet channel 130 and also over part of the suction plate 11;

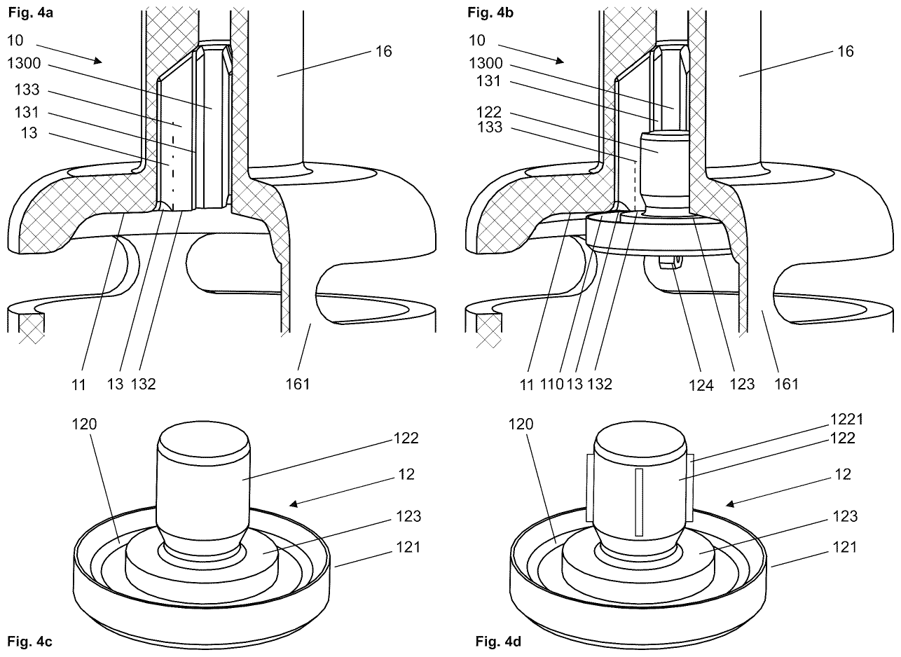

FIG. 4a a part of the suction unit 10 of FIG. 3a, in which the distribution channels 13 are provided, without the deflection unit 12;

FIG. 4b the part of suction unit 10 of FIG. 4a with the deflection unit 12 inserted;

FIG. 4c the deflection unit 12 of FIG. 4b, which has a deflection head 121 and a peg-shaped mounting element 122 adjoining the deflection head 121;

FIG. 4d the deflection unit 12 of FIG. 4c, which has a peg-shaped mounting element 122 provided with sealing bodies 1221;

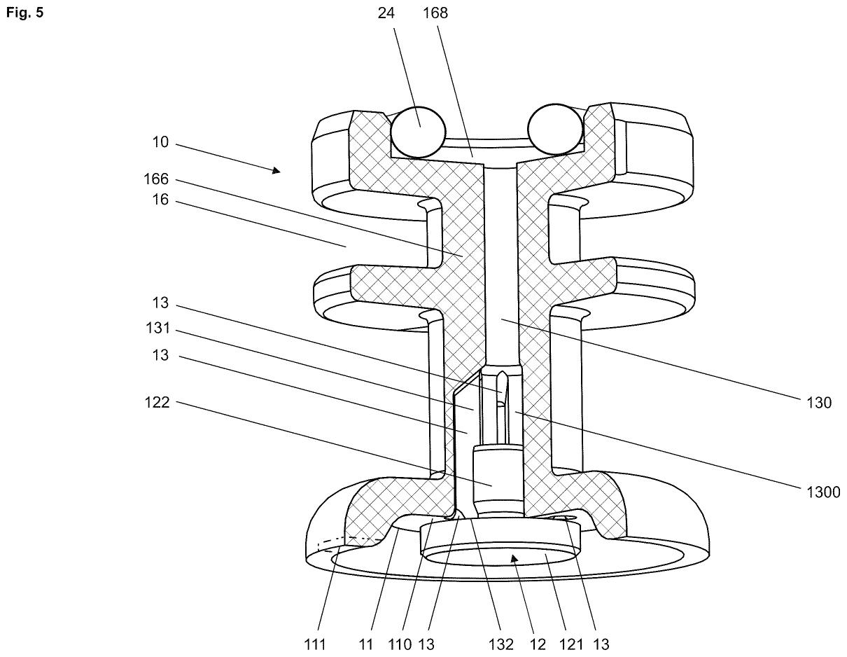

FIG. 5 the suction unit 10 of FIG. 3b without a suction basket;

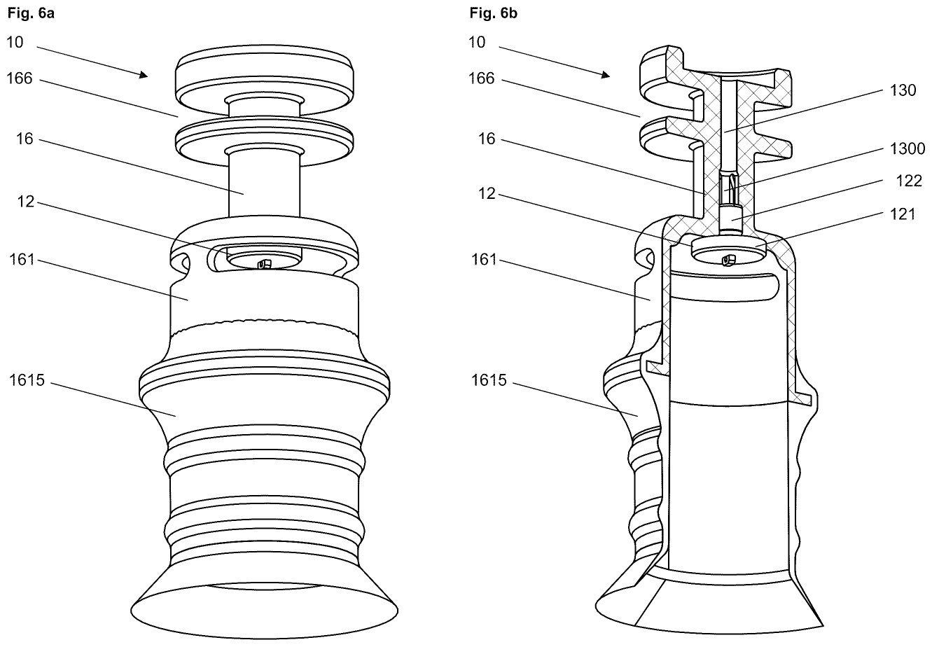

FIG. 6a the suction unit 10 of FIG. 3b with a flexible pipe section 1615 connected to the suction basket 161;

FIG. 6b the suction unit 10 of FIG. 6a in sectional view;

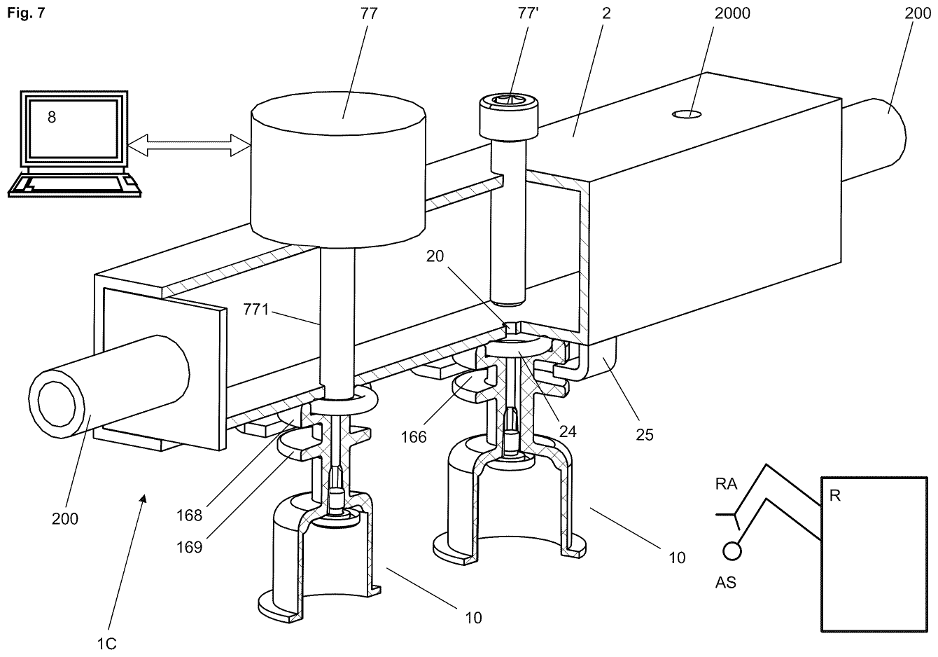

FIG. 7 a suction device 1C with a distribution device 2 in the form of a square tube, on one side of which suction units 10 are mounted as shown in FIG. 3b (shown in sectional view);

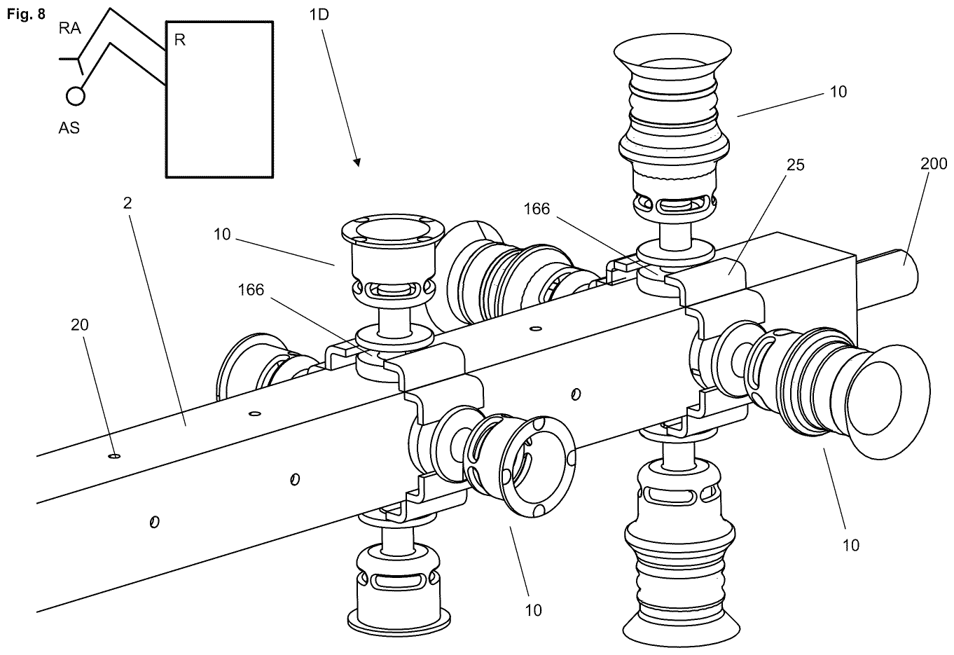

FIG. 8 a suction device 1D with a distribution device 2 in the form of a square tube, on which suction units 10 are mounted on all sides in accordance with FIGS. 3b and 6a;

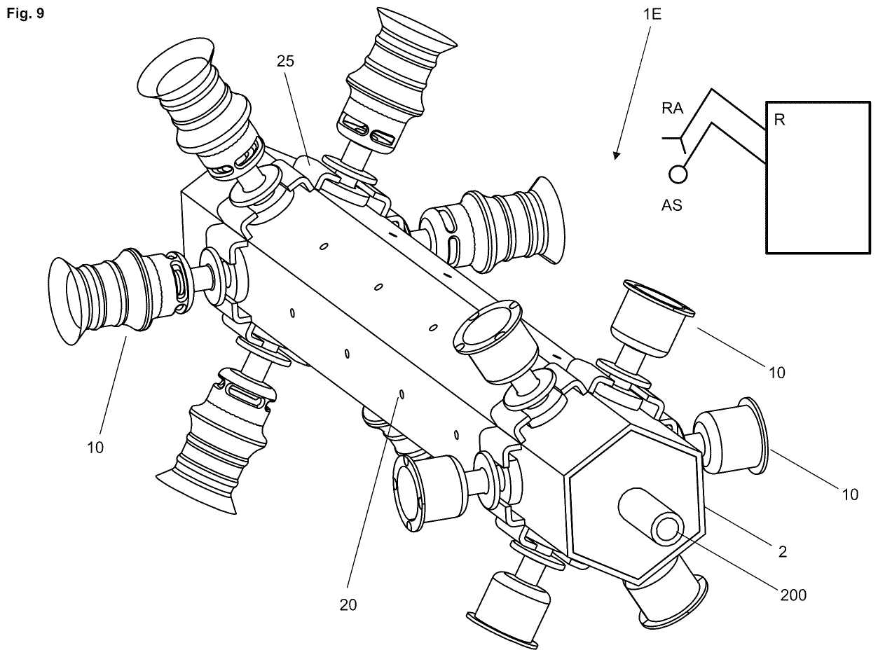

FIG. 9 a suction device 1E with a distribution device 2 in the form of a hexagonal tube, on which suction units 10 are mounted on all sides in accordance with FIGS. 3b and 6a;

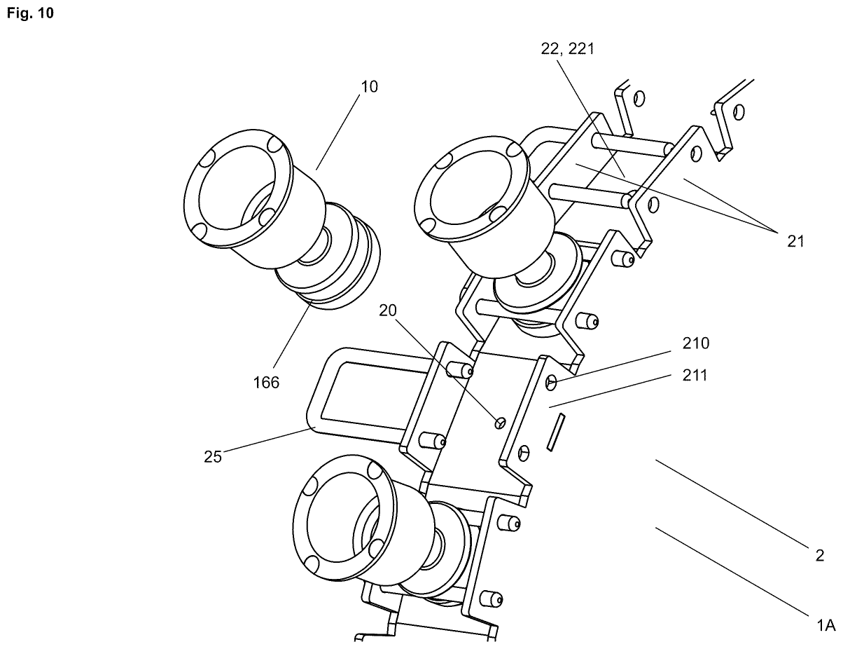

FIG. 10 a part of the suction device 1A according to FIG. 1;

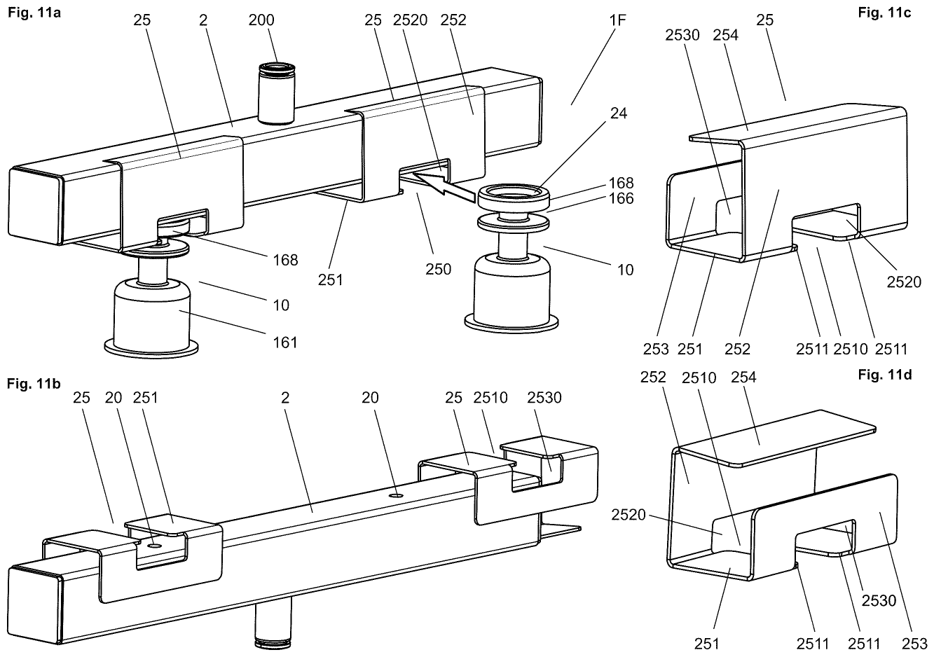

FIG. 11a a suction device 1F with a distribution device 2 in the form of a square tube 2, on which suction units 10 are mountable, for example, according to FIGS. 3b and 6a, by means of fastening elements 25 in the form of mounting clamps;

FIG. 11b the distribution device 2 of FIG. 11a rotated by 180°, showing the outlet openings 20 and two mounting brackets 25;

FIG. 11c one of the mounting clips 25 of FIG. 11a; and

FIG. 11d the mounting clamp 25 of FIG. 11c from the other side.

FIG. 1 shows a combined suction device 1 with two suction devices 1A, 1B, which are preferably equipped with suction units 10 on the periphery that operate according to the Bernoulli principle. Each suction device 1A, 1B comprises a distribution device 2, which has a circular hollow body with inlet openings 200A, 200B and peripheral outlet openings. The suction units 10 are distributed along the circumference and are each held above an outlet opening 20 by means of fastening elements 25, as shown in FIG. 10.

By means of the suction devices 1A, 1B, objects P are picked up at a pick-up location and delivered to a conveyor device 900 at a delivery location. The first suction device 1A picks up objects P, e.g. nuts, from a container B and conveys them to a transfer location, where they are transferred to the second suction device 1B, which transports the transferred objects P to the delivery location and delivers them there to the conveyor device 900.

Compressed air is supplied to each suction unit 10 through a plurality of suction channels 200A, 200B in the distribution device 2 and can be controlled individually for each of the suction units 10, so that an object P can be picked up by one suction unit 10 and simultaneously released by another suction unit 10. Each suction unit 10 can also be supplied with two pressure lines, the first of which is connected to distribution channels 13 and the second to outlet channels 14, as described with reference to FIG. 17. At the transfer point HO, a suction unit 10 of the first suction device 1A, whose object P is discharged, and a suction unit 10 of the second suction device 1B, which sucks in the object P, are located opposite each other.

The drive devices 5A, 5B of the suction devices 1A, 1B and the valves 72 of the suction channels 200A, 200B are controlled by the control unit 8 via control signals 81A, 81B; 87A, 87B. The conveyor device 900 is controlled by control signals 86 synchronously with the suction devices 1A, 1B.

A feed device 95 for the gaseous medium, e.g. a blower or an air pump, is shown as an example and can be used for all inventive suction units 10 and suction devices 1 and can be controlled, for example, by the control device 8 by means of control signals 89 in order to set a specific pressure for the medium that is fed to the valves 72, for example.

For synchronous control of device units 1A, 1B, or for checking the position and quality of objects P held by preferably transparent suction units 10, the control unit 8 preferably processes sensor signals S emitted by sensors SM, typically optical sensors or cameras.

FIG. 2 shows a cross-sectional view of a known suction unit 10′ with a deflection unit 12, which comprises a deflection head 121 and a peg-shaped mounting element 122 connected to the deflection head 121, and with a suction body 16. The suction body 16 comprises a suction plate 11 with a front side facing away from the suction body 16, an inlet channel 130 and several distribution channels 13 branching off from the inlet channel 130, through which a gaseous medium is introducible from the inlet channel 130 to the front side of the suction plate 11 into a deflection channel or annular gap 110, which is delimited on the one hand by the front side of the suction plate 11 and on the other hand by the deflection head 121 of the deflection unit 12. The distribution channels 13, which are inclined relative to the inlet channel 130, were drilled into the suction body 16, which is why the manufacture of this suction unit 10′ involves a great deal of effort and high costs.

FIG. 3a shows an inventive suction unit 10 with a suction body 16, which has a suction plate 11 with a front side facing away from the suction body 16, an inlet channel 130 and several distribution channels 13 branching off from the inlet channel 130. Along a channel segment 1300 of the inlet channel 130, the distribution channels 13 are each connected to the inlet channel 130 by a connection channel 133 and are therefore open towards the inlet channel 130.

The suction body 16 shown in the sectional view can therefore be advantageously manufactured by a forming process such as injection moulding. For example, a rod is provided which comprises elements that also correspond to distribution channels 13, the connecting channels 133 connected thereto and the inlet channel 130. The rod is inserted into a mould corresponding to the other parts of the suction body, overmoulded or cast, and removed again after completion of the forming process, whereupon the distribution channels 13, the connecting channels 133 connected thereto, and the inlet channel 130, which is connected to the distribution channels 13 by the connecting channels 133, remain and the suction body 16 is present in the configuration shown in FIG. 3a.

The suction body 16 of this suction unit 10 is provided with a holding element 166 in the form of a ring groove, which is bounded at the top by a mounting disc 168 and at the bottom by a retaining plate 169. The ring groove 166 allows the suction unit 10 to be mounted in a suction device 1A, 1B, 1C, 1D, or 1E according to FIG. 1, according to FIG. 7, FIG. 8 or FIG. 9. The holding element 166 is shown as an example and can be adapted to other suction devices as desired.

At the top of the suction unit 10, a sealing ring 24 is inserted into the mounting disc 168, which protrudes upwards beyond the edge of the mounting disc 168 and is preferably held in place by the edge of the mounting disc 168. The suction unit 10 can therefore be easily placed on a plate having outlet openings for a medium and clamped in place using a fastening element 25. The sealing ring 24, which is deformed during this process, has a dual function. On the one hand, it seals the space between the plate and the mounting disc 168. On the other hand, the suction unit 10 is pushed back by the sealing ring 24 and thus held in place without any play. The suction unit 10 is therefore particularly easy to install.

In this embodiment, the suction body 16 is integrally connected to a suction basket 161, the inner side 1619 of which is connected to the suction plate 11, wherein the suction basket 161 encloses a receiving channel 1600, which has a channel opening 1610 that is dimensioned such that individual objects P can be inserted into the receiving channel 1600 or into at least one shaping on the underside of the suction basket 161.

In preferred embodiments, the suction basket 161 has at least one basket opening 160, which is preferably located approximately at the height of the deflection head 121 of the deflection unit 12 or at a distance from the suction plate 11 in the range of 1 mm to 20 mm. It is also possible to arrange further rows of basket openings 161, as shown in FIG. 2.

The distribution channels 13 connected to the inlet channel 130 are preferably directed outwards into the edge area of the receiving channel 1600 towards the inside of the suction basket 161. The gaseous medium flowing in through the distribution channels 13, which are preferably spaced at equal angles to each other, is therefore blown against the inner wall of the suction basket 161, where it forms a thin, hollow cylindrical film that flows downwards at high velocity and, optionally, escapes through the basket openings 161. A negative pressure is formed in the flow zone, through which an object P can be sucked in. It should be noted that the object itself additionally shifts the flow outward and further reduces the flow cross-section, which is why the flow velocity and the negative pressure within the suction basket 161 increase additionally.

FIG. 3b shows the suction unit 10 of FIG. 3a with the deflection unit 12 inserted into the inlet channel 130, by means of which the distribution channels 13, starting from the front side of the suction plate 11 along part of the channel segment 1300, are closed by the inserted peg-shaped mounting element 122 and are open above the peg-shaped mounting element 122 towards the inlet channel 130.

The gaseous medium is therefore introducible from inlet channel 130 through distribution channels 13 to the front side of suction plate 11 into a deflection channel 110, which is delimited on one side by the front side of suction plate 11 and on the other side by deflection head 121 of deflection unit 12.

The deflection unit 12 shown in FIG. 4c is designed as a mushroom-shaped rotating body and comprises a deflection head 121 and a peg-shaped mounting element 122 adjoining the deflection head 121. On the side facing the suction plate 11, the deflection head 121 has a circumferential groove-shaped recess 120, which preferably extends in a rounded manner towards the edge of the deflection head 121. In a section through the axis of rotation, the deflection unit thus has at least approximately an anchor-shaped cross-section. This forms a ring nozzle within which inflowing air is guided back towards the suction plate 11 and flows along the latter at high speed, preferably radially outwards, resulting in a negative pressure.

FIG. 4a shows a part of the suction unit 10 of FIG. 3a, in which the distribution channels 13 are provided. The quarter section through the suction body 16 shows that the inlet channel 130 extends to the front side of the suction plate 11 and that the distribution channels 13 branch off from the inlet channel 130 in a channel segment 1300 of the inlet channel 130 and extend to the front side of the suction plate 11 and are each connected to the inlet channel 130 via a connection channel 133 over the entire channel segment 1300. The distribution channel 13, which is exposed by the quarter section, is separated from the connection channel 133 by a dotted line. The connection channel 133 is opened towards the inlet channel 130 by a first channel opening 131 and downwards towards the front side of the suction plate 11 by a second channel opening 132.

To close these two channel openings 131, 132, either the deflection unit 12 of FIG. 4c or FIG. 4d or the closure member 1200 is used, which has a sealing sleeve 1201 and a ring flange 1202. If the closure member 1200 is inserted into the inlet channel 130 at the front, the deflection unit 12 is inserted with the mounting element 122 into the sealing sleeve 1201 of the closure member 1200. When inserting the deflection unit 12 of FIG. 4c or the closure part 1200 of FIG. 3b, the connection channels 133 between the first channel opening 131 and the second channel opening 132 of the distribution channels 13 are closed. At the front, the connection channels 133 are closed by a sealing ring 123, which connects to the mounting element 122 of the deflection unit 12, or by the ring flange 1202 of the closure part 1200.

In the embodiment shown in FIG. 4d, the mounting element 122 is provided with sealing bodies 1221 corresponding to the number of distribution channels 13, which can be inserted into the connection channels 133 to close them. The sealing bodies 1221 simultaneously close both channel openings 131, 132.

The sealing bodies 1221 are preferably complementary to the connecting channels 131, for example rib-shaped. The sealing bodies 1221 preferably extend parallel to the longitudinal axis x of the mounting element 122 or the sealing sleeve 1201 so that the mounting element 122 or sealing sleeve 1201 can be inserted unhindered into the inlet channel 130 at the front side of the suction plate 11.

After insertion of the deflection unit 12 or the closure part 1200, the distribution channels 13 between the inlet opening 131 and the outlet opening 132 are closed as well as the distribution channels 13 in the suction unit of FIG. 2.

FIG. 5 shows the suction unit 10 of FIG. 3b without the optional suction basket 161. Suction units 10 without suction basket 161 are typically used to pick up and deliver flat objects. Suction units 10 with a suction basket 161, on the other hand, allow objects of any shape to be picked up.

The suction plate 11 may extend in a plane to the outer edge or may be curved. Preferably, recesses, depressions or suction channels 111 are provided in the parts of the suction unit 10 that grip an object, which ensure that the media flow is maintained when an object is coupled.

FIG. 6a shows the suction unit 10 of FIG. 3b with a flexible pipe section 1615 connected to the suction basket 161. The pipe section 1615 is preferably designed as an elastic bellows that can align itself with an object. The use of this suction unit 10 is particularly advantageous in suction devices 1C, 1D, 1E of FIG. 7, FIG. 8 and FIG. 9, which have a straight or tubular distribution device 2.

FIG. 6b shows a sectional view of the suction unit of FIG. 6a. It shows that the suction basket 161 and the pipe section 1615 are connected to each other in a form-fitting manner.

An inventive suction unit 10 can be used as a single unit and connected to a compressed air line. During surgical procedures, a single suction unit 10 can be used to collect loose parts or tools, thereby advantageously avoiding the suction of liquids and contamination of the suction unit 10. In production processes where numerous products are transported on a conveyor, it is desirable to use suction devices that hold several suction units 10.

Inventive suction devices 1, which have several outlet openings 210 and associated fastening elements or mounting means 25, can be equipped with a corresponding number of inventive or conventional suction units 10, which have holding elements 166, 168 corresponding to the mounting means 25. Normally, suction units of the same type, for example of FIG. 3b, FIG. 5 or FIG. 6a, are always used in a suction device 1. However, it is also possible to combine suction units 10 of different types in a suction device 1. The suction device of FIG. 7 is equipped with suction units 10 according to FIG. 3b. Alternatively, only suction units 10 according to FIG. 6a can be used. Suction devices 1 with several suction units 10 allow a series of objects to be picked up and released again in one step or sequentially in several steps.

FIG. 7 shows a simple suction device 1 with two device connections, each of which has a suction unit 10 mounted on it in accordance with FIG. 3b, which has a suction body 16 with a holding element 168 designed as a mounting disc, to which a ring groove 166 adjoins.

The suction device 1 comprises a distribution device 2, which comprises a hollow body in the form of a square tube having two inlet openings 200 and several outlet openings 20. Fastening elements in the form of mounting brackets 25 are provided at each outlet opening, which are firmly connected to the distribution device 2 and form a device connection at the outlet opening 20. The mounting brackets 25 are firmly connected to the square tube, optionally by welding.

The square tube 2 has inlet openings 200 on the front side, outlet openings 20 on the underside, and mounting openings 2000 on the top side, if necessary. As described with reference to FIG. 3a, the suction units 10 can be easily mounted by means of the mounting brackets 25, which engage in the ring groove 166. The suction unit 10 to be mounted is pressed against the corresponding side of the square tube 2, thereby deforming the sealing ring 24 and allowing the suction body 16 with the ring groove 166 to be inserted into the mounting brackets 25. As a result, the suction body 16 is pressed against the mounting brackets 25 by the elastic sealing ring 24, for example a rubber ring, and held in place without any play. At the same time, the inlet opening 130 and the outlet openings 20 are tightly enclosed by the sealing ring 24.

There is no need to use assembly tools such as screwdrivers, pliers, spanners or similar. The suction units 10 can be assembled in a single step.

Also shown are a mechanical actuator 77′ and a controllable electromechanical actuator 77, by means of which the flow of the medium through the outlet openings 20 can be adjusted.

The electromechanical actuator 77 has, for example, an actuator part 771 which can be extended and retracted under the control of a control unit 8 in order to close or reopen the outlet openings 20 completely or partially. Preferably, each suction unit 10 is assigned such an actuator 77 so that they can be controlled individually or in groups to pick up and release objects P.

Also shown is a manipulating device R, for example a robot, with an actuating element RA, for example a robot arm, with which the square tube 2 can be held and optionally moved. It is also shown that the manipulating device R has a media connection AS, for example a compressed air connection, which is connected to the inlet opening 200.

FIG. 8 shows a suction device 1D with a distribution device 2 in the form of a square tube, on which suction units 10 are mounted on all sides in accordance with FIGS. 3b and 6a. The distribution device 2 is not yet fully equipped, which is why individual outlet openings 20 are exposed. For example, six rows with different types of suction units 10 can be mounted.

In practice, suction units 10 of the same type are usually always used on one side of the distribution device 2. Again, a manipulating device R is shown, by means of which the distribution device 2, which comprises a square tube, can be selectively manipulated and moved between a pick-up position and a delivery position. Furthermore, the manipulating device R is designed to be able to perform quarter turns of the distribution device 2 so that the suction units 10 on each side of the distribution device 2 can sequentially pick up and release objects P in rows.

FIG. 9 shows a suction device 1E with a distribution device 2 in the form of a hexagonal tube, on which suction units 10 are mounted on all sides in accordance with FIGS. 3b and 6a. The distribution device 2 is not yet fully equipped. Preferably, the same suction units 10 are used on each side of the distribution device 2. For example, six rows with different types of suction units 10 can be mounted. In this case, the manipulating device R is capable of performing stepwise rotations of the distribution device 2 by 60° so that the suction units 10 on each side of the distribution device 2 can sequentially pick up and release objects P in rows.

In preferred embodiments, the suction devices 1D and 1E of FIG. 8 and FIG. 9 are equipped with different suction units 10 on at least two sides of the distribution device 2. For example, suction units 10 according to FIG. 3b are provided on one side, while suction units 10 according to FIG. 6a are mounted on the other side and suction units 10 according to FIG. 5 are possibly mounted on the next side.

The suction devices 1 are equipped with suction units 10 according to the objects P to be picked up. If flat objects P are to be picked up, suction units 10 without suction basket 161 are preferably used, for example as shown in FIG. 5. If objects P with the same or different shapes but approximately the same size are to be picked up, suction units 10 with a suction basket 161, for example as shown in FIG. 3b, are preferably used. If objects P with the same or different shapes and different sizes are to be picked up, suction units 10 with an elastic tube or bellows 1615, for example as shown in FIG. 6a, are preferably used. If a large object P and a small object P need to be picked up, the first suction unit 10 according to FIG. 6a can pick up the large object P, while the suction device 1 is lowered further until the second suction unit 10 according to FIG. 6a or FIG. 3b can pick up the smaller second object P. During this process, the elastic bellows 1615 of the first suction unit 10 according to FIG. 6a is deformed or compressed accordingly. If different objects P are to be picked up, it may therefore be advantageous to use a series of suction units 10 of different types.

It is also possible to combine the suction unit 10 shown in FIG. 5 with an elastic tube or bellows 1615 and use it accordingly.

FIG. 10 shows part of the suction device 1A of FIG. 1. The distribution device 2 is circular in shape and comprises two side plates 21 which peripherally delimit a circular frame 22 having plates 221 which are inclined towards each other along the circumference and are each provided with an outlet opening 20. The suction units 10 can therefore be mounted in the same way as the suction devices of FIG. 7, FIG. 8 and FIG. 9. Only the mounting means 25 are designed differently. The mounting bracket 25 is not permanently mounted but is inserted into the ring groove 166 of the suction body 16. For this purpose, the site plates 21 for each of the plates 221 are provided with retaining flanges 211, each of which is provided with mounting openings 210 into which a mounting bracket 25 can be inserted. Mounting brackets 25 are preferably rod-shaped and U-profile-shaped.

The parts of the suction devices 1 are made of metal or plastic. It is possible to combine plastic device parts with metal device parts.

FIG. 11a shows another suction device 1F with a distribution device 2 in the form of a square tube 2, to which suction units 10 are mountable, for example, in accordance with FIG. 3b and FIG. 6a by means of fastening elements 25. The fastening elements 25 are designed as mounting clips and are not permanently connected to the distribution device 2 but can be attached and removed as required. Therefore, no mounting means need to be provided on the distribution device 2, which is why this suction device 1F can be manufactured with minimal effort. Individual mounting clips 25 must therefore be provided in a number corresponding to the number of outlet openings 20 on the distribution device 2.

A first mounting clip 25 was placed on the square tube 2. A second mounting clip 25 is pushed onto the square tube 2 from the side. Due to the elastic design of the mounting clips 25, they can be stretched and preferably also placed frontally on the square tube 2.

A suction unit 10 has been inserted into one of the mounting clips 25 and is pressed against the distribution device 2 by means of the mounting clip 25. Another suction unit 10 is ready for installation.

FIG. 11b shows the distribution device 2 of FIG. 11a rotated by 180°, with a view to the outlet openings 20 and the two mounting clips 25. FIG. 11c shows one of the mounting clips 25 of FIG. 11a. FIG. 11d shows the mounting clip 25 of FIG. 11c from the other side.

The mounting clips 25 comprise a base plate 251, to which two sidewalls 252, 253 are connected, and a downwardly inclined cover plate 254, which is connected to the first sidewall 252 on the side opposite the base plate 251. The base plate 251 has a mounting slot 2510, to which an access opening 2520; 2530 is adjoined on each of the sidewalls 252, 253, which is wider than the mounting slot 2510 and into which the mounting disc 168 of a suction unit 10 is insertable.

FIGS. 11c and 11d show that the base plate 251 has flange elements 2511 facing each other, which, as shown in FIG. 11a, engage in a ring groove 166 of the suction unit 10 and limit the mounting slot 2510, which is tapered opposite the receiving openings 2520, 2530, and which, as shown in FIG. 11a, can engage in a ring groove 166 of the suction unit 10 and hold the mounting disk 168 located above it.

The mounting clips 25 are preferably made of elastic material, such as plastic or metal, possibly spring steel. The downwardly inclined cover plate 254 can therefore advantageously serve as a spring element which pulls the mounting clips 25 and a mounting disk 168 held therein upwardly against the square tube 2, so that the mounting disk 168 and a sealing ring 24 preferably held in the mounting disk 168 (see FIG. 5) held preferably in the mounting disk 168 tightly enclose the associated outlet opening 20.

FIG. 11a shows that the mounting disc 168 can be inserted into the access opening 2520 of the mounting clip 25 so that the ring groove 166 is held in the mounting slot 2510.

The distribution device 2 can therefore be equipped with suction units 10 using inventive fastening means 25. For example, an outlet opening 20, preferably closed by a screw, is cleared, a mounting clip 25 is attached and the suction unit 10 is inserted, or a suction unit 10 is attached and fixed by a mounting bracket 25.

In all designs of suction devices 1, the suction units 10 can be easily mounted on a suction device without tools.

1. A suction unit, suitable for suctioning an object according to the Bernoulli principle, with a deflection unit which comprises a deflection head and a peg-shaped mounting element adjoining the deflection head and a suction body,
which suction body has a suction plate with a front side facing away from the suction body,
which suction body has an inlet channel which extends through the suction body to the front side of the suction plate and into which inlet channel the peg-shaped mounting element is inserted from the front side of the suction plate, and
which suction body has a plurality of distribution channels branching off from the inlet channel,
wherein through the distribution channels a gaseous medium is introducible from the inlet channel to the front side of the suction plate into a deflection channel, which is delimited on one side by the front side of the suction plate and on the other side by the deflection head of the deflection unit, wherein along a channel segment of the inlet channel the distribution channels are each connected to the inlet channel by a connection channel, which connection channel is closed starting from the front side of the suction plate along a part of the channel segment by the inserted peg-shaped mounting element or a closure member and is open above the peg-shaped mounting element towards the inlet channel.

2. The suction unit according to claim 1, wherein the suction body has a longitudinal axis and that the distribution channels are arranged at regular or irregular intervals from each other and extend conically, concentrically to the longitudinal axis or along a curve outward to the suction plate.

3. The suction unit according to claim 1, wherein the suction body was manufactured by a primary forming process or that the suction body was manufactured by injection moulding.

4. The suction unit according to claim 1, wherein each of the connection channels has a first channel opening adjoining the channel segment of the inlet channel and a second channel opening adjoining the front side of the suction plate.

5. The suction unit according to claim 1, wherein the deflection unit has a sealing ring adjoining the mounting element or that the closure member has a sealing sleeve and a ring flange, and the mounting element of the deflection unit is held in the sealing sleeve.

6. The suction unit according to claim 1, wherein the mounting element is provided with sealing bodies corresponding to the number of distribution channels, which can be inserted into the connection channels in order to close them, wherein the sealing bodies are preferably rib-shaped and extend parallel or in a plane radial to the longitudinal axis.

7. The suction unit according to claim 1, wherein the suction body is connected integrally or detachably to a suction basket, the inside of which is connected to the suction plate or the inside of which is spaced apart from the suction plate, wherein the suction basket encloses a receiving channel which has a channel opening which is dimensioned such that individual objects can be introduced into the receiving channel or into at least one shaping on the underside of the suction basket.

8. The suction unit according to claim 7, wherein the suction basket has at least one basket opening which is preferably located approximately at the height of the deflection head of the deflection unit or at a distance from the suction plate.

9. The suction unit according to claim 7, wherein the channel opening of the suction basket is enclosed by a ring plate aligned perpendicular or inclined to the suction basket.

10. The suction unit according to claim 1, wherein the suction body has at least one holding element such as a shaping, an opening or a ring groove, or a mounting disc, by means of which the suction body is mountable on a connection of a device.

11. A device with multiple device connections, on which in each case a suction unit according to claim 1 is mounted, which has a suction body with a holding element, wherein a distribution device, which has a hollow body with at least one inlet opening and with multiple outlet openings, and fastening elements are provided, which are connected to the distribution device in a fixed or detachable manner and which each form a device connection at an outlet opening and which each hold an associated suction unit on the holding element above an associated outlet opening.

12. The suction device according to claim 11, wherein the fastening elements are designed as mounting clips, which are made of elastic material and which comprise a base plate that is adjoined by two sidewalls and a cover plate, which is preferably inclined downwards and which, on the side opposite the base plate, is connected to one of the sidewalls, and that the base plate has a mounting slot, which is adjoined at least on one of the sidewalls by an access opening which is wider than the mounting slot and into which the mounting disc of a suction unit is insertable or inserted.

13. The suction device according to claim 11, wherein the distribution device is circular, plate-shaped or wheel-shaped and has two side plates and, preferably, a circular frame on the periphery, and that the outlet openings and the fastening elements are fastened to the side or to the circular frame.

14. The suction device according to claim 11, wherein the distribution device has a polygonal cross-section with several sides, one or more of which are provided with outlet openings and fastening elements by which the mounted suction units are held.

15. The suction device according to claim 1, wherein the outlet openings can be selectively closed completely or partially by mechanical or controllable electromechanical closing devices.
